(19) United States
(12) Patent Application Publication
(10) Pub. No.: US 2026/0361308 A1
(43) Pub. Date: Nov. 12, 2026

(54) COUNTING MODULE, ACCUMULATION-COMPARISON DEVICE AND ASSOCIATED NEUROMORPHIC CIRCUITS

(71) Applicants: Commissariat à l’Energie Atomique et aux Energies Alternatives, Paris (FR); Centre national de la recherche scientifique, Paris (FR); UNIVERSITE GRENOBLE ALPES, Saint Martin D'heres (FR); INSTITUT POLYTECHNIQUE DE GRENOBLE, Grenoble (FR)

(72) Inventors: Mona EZZADEEN, Grenoble Cedex 9 (FR); Joel MINGUET LOPEZ, Grenoble Cedex 9 (FR); Manon DAMPFHOFFER, Grenoble Cedex 9 (FR); Gabriele NAVARRO, Grenoble Cedex 9 (FR); Renzo ANTONELLI, Villeurbanne (FR)

(73) Assignees: Commissariat à l’Energie Atomique et aux Energies Alternatives, Paris (FR); Centre national de la recherche scientifique, Paris (FR); UNIVERSITE GRENOBLE ALPES, Saint Martin D'heres (FR); INSTITUT POLYTECHNIQUE DE GRENOBLE, Grenoble (FR)

(21) Appl. No.: 19/457,275

(22) Filed: Jan. 23, 2026

(30) Foreign Application Priority Data
Jan. 23, 2025 (FR) FR2500703

(51) Int. Cl. H03K 21/02; G06N 3/063; G11C 11/54; G11C 13/00

(52) U.S. Cl. CPC H03K 21/02; G06N 3/063; G11C 11/54; G11C 13/003

(57) ABSTRACT

The present invention relates to a module for counting (12) a number of detections of events in a counting time interval comprising:
an input unit (18) receiving a signal of detection of an event in the counting time interval,
a selection component (20), the selection component (20) comprising a selector comprising an active layer made of a chalcogenide material, the selector (26) switching between two resistive states and a second resistive state in the presence of a switching pulse,
an application unit (22) applying a counting pulse on the selector (26) for each detection signal received by the input unit (18), and
a unit (24) for resetting the counting time interval by application of a resetting pulse on the selector (26).

The present invention relates to a counting module. The present claim also relates to systems comprising the counting module, namely a device adapted to carry out an accumulation operation and a comparison operation, an electronic circuit implementing a neuron and a neuromorphic circuit adapted to implement a neural network with a binary output.

For multiple applications, among which automatic data processing, diagnostic assistance, predictive analysis, autonomous vehicles, bioinformatics or monitoring, it is known to use automatic learning algorithms forming part of programs that can be executed on processors such as CPUs or GPUs. A CPU is a processor, the acronym CPU coming from the English term “Central Processing Unit” meaning literally central processing unit while a GPU is a graphics processor, the acronym GPU coming from the English term “Graphics Processing Unit” meaning literally graphics processing unit.

Among the techniques for implementing learning, the use of neural networks is increasingly widespread, these structures being considered very promising because of their performance for numerous tasks such as automatic data classification, pattern recognition, translation and automatic language understanding, robotic control, automatic navigation, recommendation systems, anomaly detection, fraud detection, the study of DNA or also the discovery of new molecules.

A neural network is generally composed of a succession of layers of neurons each of which takes its inputs on the outputs of the preceding layer. More precisely, each layer comprises neurons taking their inputs on the outputs of the neurons of the preceding layer. Each layer is connected by a plurality of synapses. A synaptic weight is associated with each synapse. It is a real number, which takes positive as well as negative values. For each layer, the input of a neuron is the weighted sum of the outputs of the neurons of the preceding layer, the weighting being done by the synaptic weights.

For an implementation in a CPU or a GPU, a Von Neumann bottleneck problem (also called “Von Neumann bottleneck” according to its English designation) appears because the implementation of a deep neural network (with more than three layers and going up to several dozen) involves using both the memory or memories and the processor while these latter elements are spatially separated. This results in congestion of the communication bus between the memory or memories and the processor both while the neural network once trained is used to carry out a task, and, a fortiori, while the neural network is trained, that is to say while its synaptic weights are adjusted to solve the task in question with maximum performance.

It is therefore desirable to develop dedicated hardware architectures, intermixing memory and computation, to produce fast, low-consumption neural networks capable of learning in real time.

A neural network based on optical-type technologies is known.

Another research field relates to the production of neurons and synapses of neural networks on the basis of CMOS-type technology. By the acronym “CMOS” is meant complementary metal-oxide semiconductor (acronym coming from the English expression “Complementary Metal-Oxide-Semiconductor”). The acronym CMOS denotes both a manufacturing process and a component obtained by such a manufacturing process.

However, according to each of these technologies, each neuron occupies several tens of micrometers on a side. In addition, each synapse also occupies several tens of micrometers on a side. It results therefrom that, on a limited surface corresponding for example to an electronic chip, the number of neurons and synapses that can be integrated is limited, which results in a reduction in the performance of the neural network.

Because of this, to reduce bulk, architectures in which the synapses are memristive are specifically studied.

Memristive synapses are synapses using memristors. In electronics, the memristor (or memristance) is a passive electronic component. The name is a portmanteau formed from the two English words memory and resistor. A memristor is a non-volatile memory component, the value of its electrical resistance changing with the application of a voltage or a current for a certain duration and remaining at this value in the absence of voltage, respectively of current.

An example of such an implementation is proposed in an article by L. Wang et al. entitled “Efficient and Robust Nonvolatile Computing-In-Memory based on Voltage Division 2T2R RRAM with Input-Dependent Sensing Control” published on Mar. 19, 2021 in the journal Transactions on Circuits and Systems II: Express Briefs.

In this proposal, a resistive bridge is used. This approach is based on the ratio of complementary weights. Moreover, in each 2T2R cell (2 transistors-2 resistors), the current always passes through a sum of resistances in series, instead of a single resistance. Consequently, this approach allows a non-negligible reduction of the current consumption.

However, despite these advantages, this technique is also limited its reliable use to neurons with 9 inputs.

Another approach is that of an article by S. Jung et al. entitled “A crossbar array of magnetoresistive memory devices for in-memory computing” published in Nature 2022 consisting in connecting the resistive weights in series instead of connecting them in parallel. The weights are stored in 2T2R cells whose two transistors are activated differentially. The operation of multiplication between an input and a weight is done by applying the input on the word line (WL for “word line”) of the 2T2R cell, thus selecting only one of the two resistive elements, whose value is given by the weight. A voltage is applied to one of the ends of the series of weights, which makes it possible to generate a weighted current corresponding to the accumulation-comparison operation (MAC operation) between the weights and the inputs. This current charges a capacitance at the bottom of the column. The voltage of the capacitance is compared to a reference in time, thus making it possible to digitize the value of the MAC over several bits thanks to digital control.

The connection of all the weights in series makes it possible to reduce the current consumption compared to the two preceding solutions, however, the access transistors also being connected in series with the weights, they must be large in size so as not to interfere with the computation.

Moreover, this technique remains very sensitive to the variability of the resistive cells (with a maximum demonstrated neuron size of 64 inputs), and can suffer from delay errors that depend on the combination of activated weight.

There therefore exists a need for a counting module making it possible to carry out certain operations of a binary neural network that presents better integrability in an assembly of memory cells.

To this end, the description has as its object a module for counting a number of detections of events in a counting time interval, the counting module comprising:
an input unit adapted to receive a signal of detection of an event in the counting time interval,
a selection component, the selection component comprising a selector comprising a first electrode, a second electrode and an active layer disposed between the first electrode and the second electrode, the active layer being made of a chalcogenide material,
the selector being adapted to switch between a first resistive state and a second resistive state in the presence of a switching pulse applied between the two electrodes, the first resistive state being more resistive than the second resistive state, a switching pulse being a pulse having an amplitude exceeding a threshold voltage value and applying a current on the selector higher than the holding current of the selector in the second resistive state,
an application unit adapted to apply a counting pulse on the selector for each detection signal received by the input unit,
each counting pulse being a switching pulse having a first predefined shape increasing the value of the threshold voltage of the selector, the threshold voltage value of the selector thus being representative of the number of detections of events, and
a unit for resetting the counting time interval, the resetting unit being adapted to apply at least one resetting pulse on the selector, a resetting pulse being a switching pulse having a second shape and decreasing the threshold voltage of the selector to a minimum threshold voltage value of the selector.

According to other advantageous aspects, the counting module comprises one or more of the following features, taken alone or according to all technically possible combinations:
each switching pulse has a rising edge, a plateau at a maximum value and a falling edge, the ratio between the duration of the sum of the plateau and of the falling edge for the second predefined shape and the duration of the sum of the plateau and of the falling edge for the first predefined shape being greater than or equal to 2, preferably greater than or equal to 10.
the duration of the plateau of a resetting pulse is greater than or equal to 200 ns.
the duration of the falling edge of a resetting pulse is greater than or equal to 200 ns.
the duration of the falling edge of a counting pulse and the duration of the plateau of a counting pulse are each less than or equal to 100 ns.
the input unit comprises a sub-unit for converting the signal of detection of an event received into a counting pulse.
the selection component further comprises a resistive memory, the resistive memory having at least two distinct resistance values, the resistive memory being interposed between an electrode and the active layer, the threshold voltage value of the selector also depending on the resistance value of the resistive memory.

The description also has as its object a device adapted to carry out an accumulation operation and a comparison operation, the device comprising a counting module as defined previously, the application unit being adapted to apply counting pulses having an amplitude equal to a threshold voltage value of the selector corresponding to a threshold of detections of events to be reached, the device further comprising:
a comparison unit adapted to compare a quantity representative of the value of the threshold voltage of the selector with a quantity representative of a predefined threshold voltage, the predefined threshold voltage corresponding to a predefined number of counting pulses, to obtain a comparison result, and
a unit for storing the result of the comparison.

According to other advantageous aspects, the device comprises one or more of the following features, taken alone or according to all technically possible combinations:
the comparison unit comprises a current comparator, the quantity representative of the value of the threshold voltage of the selector being the output current of the selector and the quantity representative of the predefined threshold voltage being a current value.
the storage unit is a flip-flop.
the application unit is a transistor.
the resetting unit is a transistor.

The description also relates to an electronic circuit implementing a neuron comprising a device as previously described.

The description also has as its object a neuromorphic circuit adapted to implement a neural network with a binary output, the neuromorphic circuit comprising at least one electronic circuit implementing a neuron as previously described.

In the present description, the expression “suitable for” means indifferently “adapted for,” “adapted to” or “configured for.”

The invention will appear more clearly on reading the description that follows, given only by way of non-limiting example, and made with reference to the drawings in which:

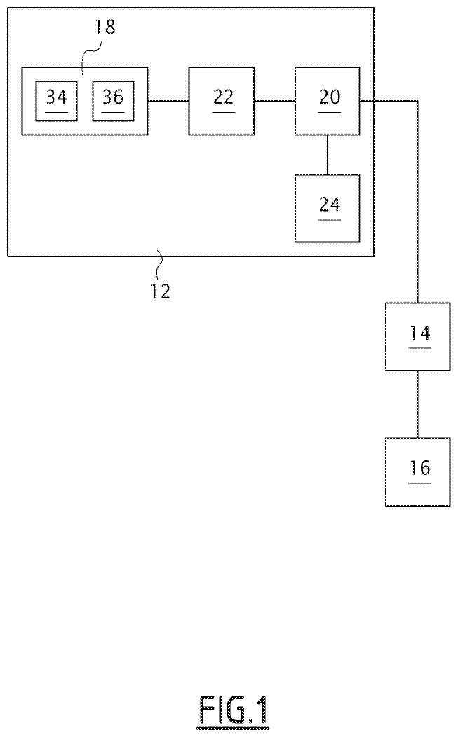

FIG. 1 is a schematic representation of an accumulation-comparison device, that is to say a device carrying out an accumulation and comparison operation,

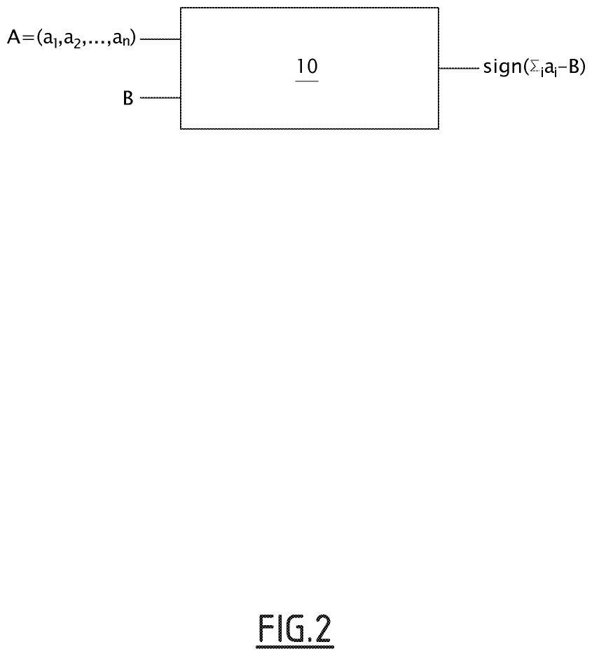

FIG. 2 is a schematic representation of the operation of an accumulation-comparison device,

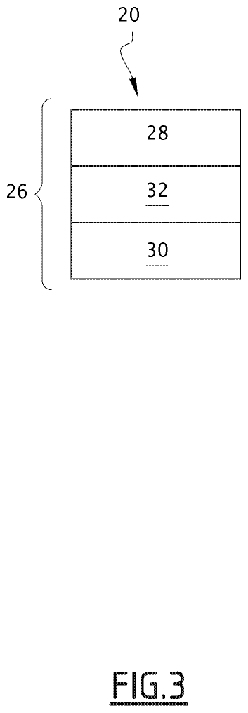

FIG. 3 is a representation of the layers of a selection component forming part of the accumulation-comparison device of FIG. 1, the selection component being a selector based on chalcogenide material,

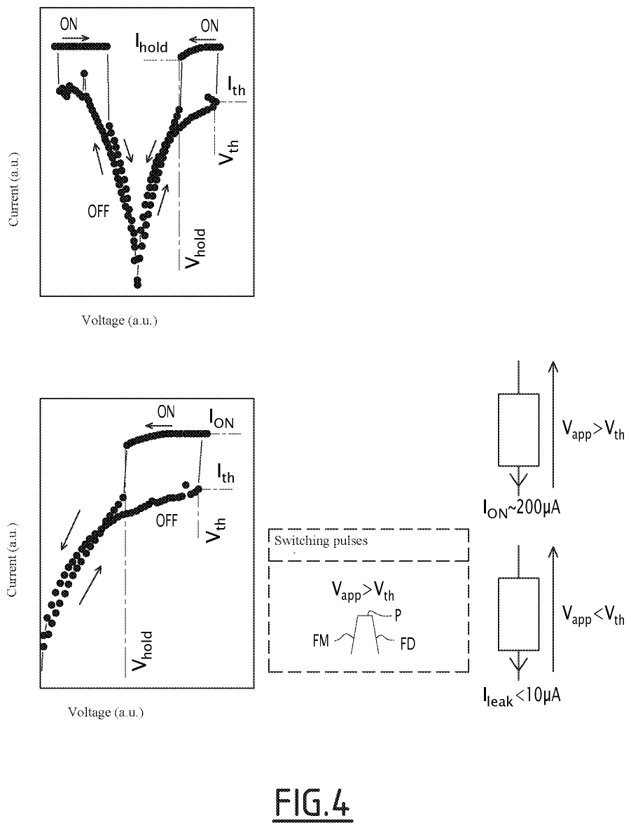

FIG. 4 comprises graphs each illustrating a current-voltage characteristic curve of an OTS selector having two resistive states,

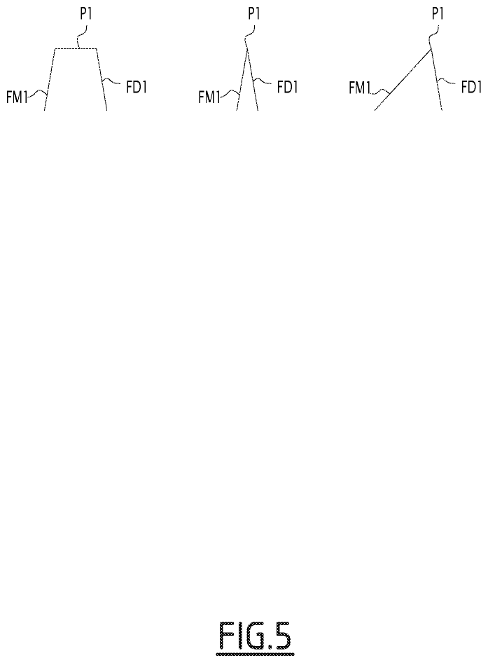

FIG. 5 presents examples of a first shape of switching pulse leading to an increase in the threshold voltage value of the selector,

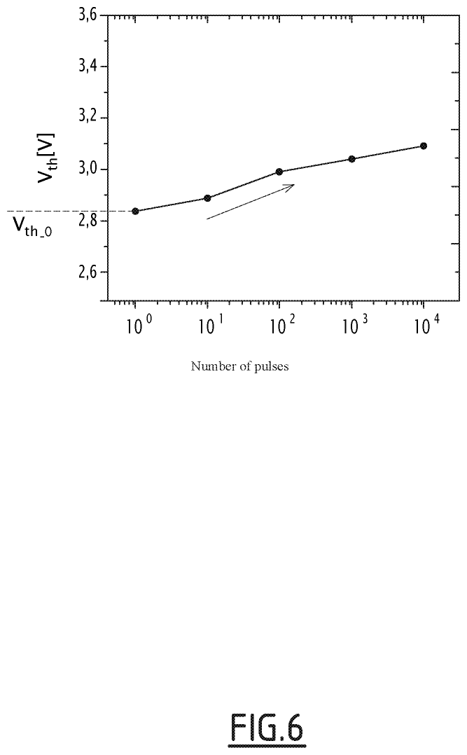

FIG. 6 presents an example of evolution of the value of the threshold voltage of the selector as a function of number of pulses of first shape applied on the selector,

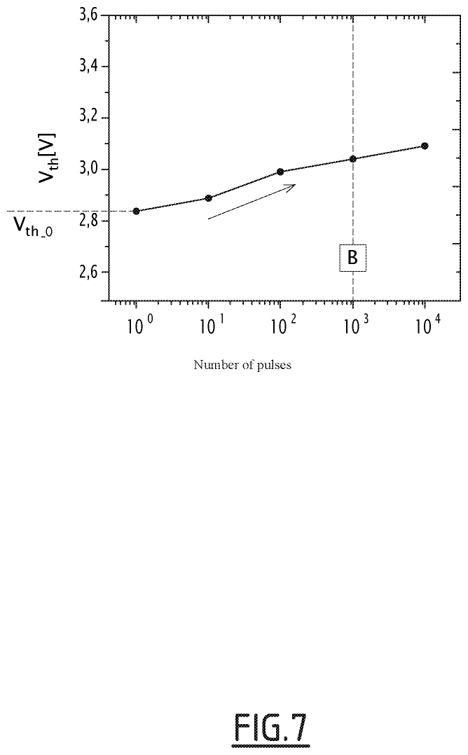

FIGS. 7 to 10 schematically illustrate an operation of the selector of FIG. 3 to carry out the accumulation and comparison operation of FIG. 2,

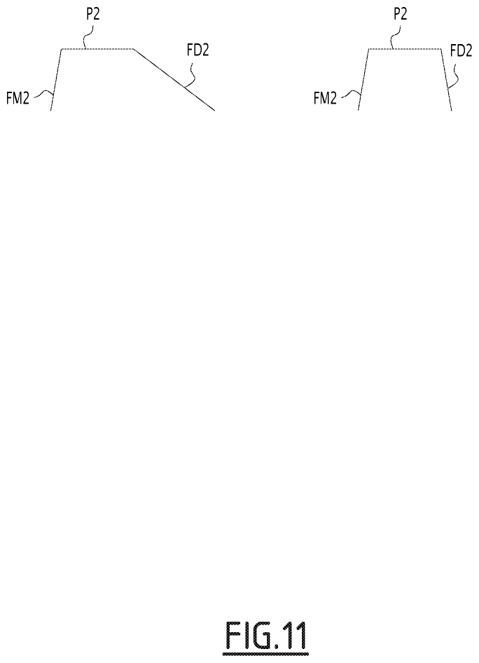

FIG. 11 presents examples of a second shape of switching pulse leading to a resetting of the threshold voltage value of the selector,

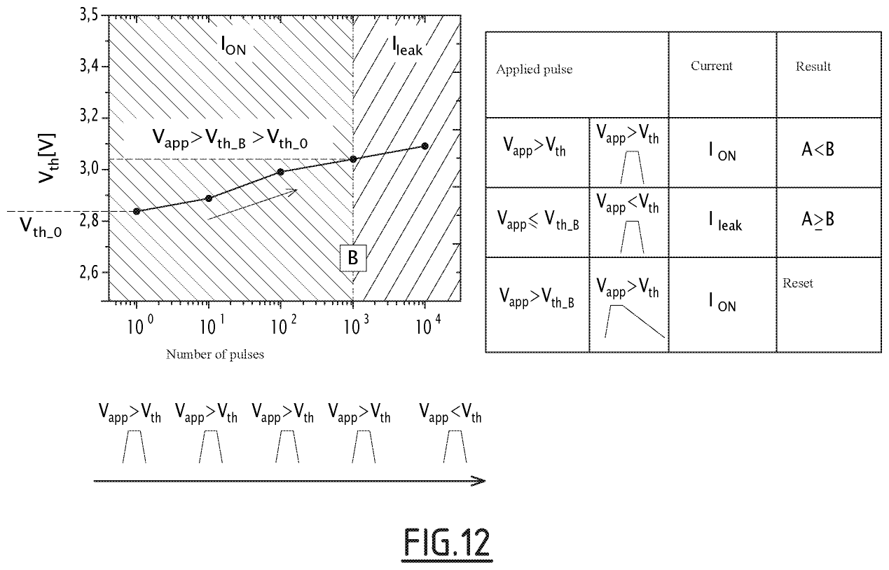

FIG. 12 schematically illustrates an operation of the selector of FIG. 3 to carry out a resetting for the accumulation and comparison operation of FIG. 2,

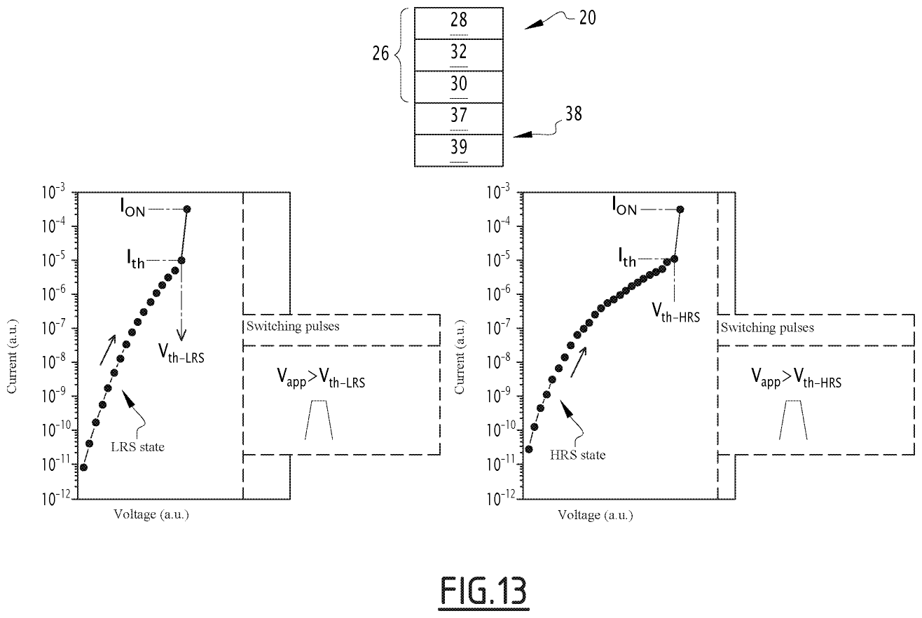

FIG. 13 represents two graphs illustrating respectively a current-voltage characteristic curve of a selection component formed by a selector based on chalcogenide material in series with a phase-change memory for two values of the phase-change memory, the selection component being schematized above the two graphs,

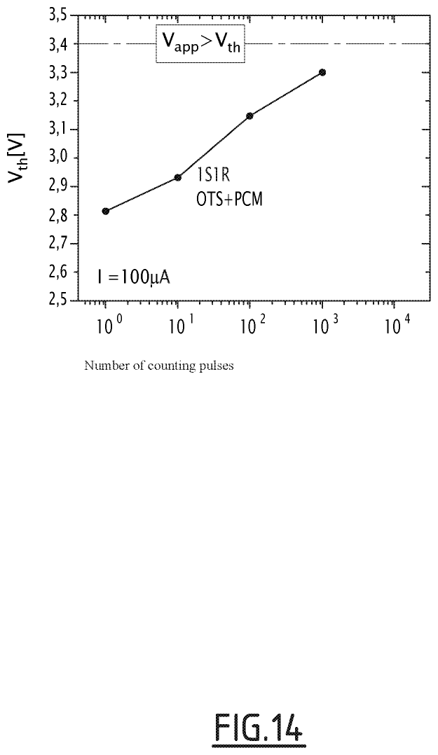

FIG. 14 is a graph showing the evolution of the switching voltage as a function of a number of counting pulses applied to the selection component of FIG. 13,

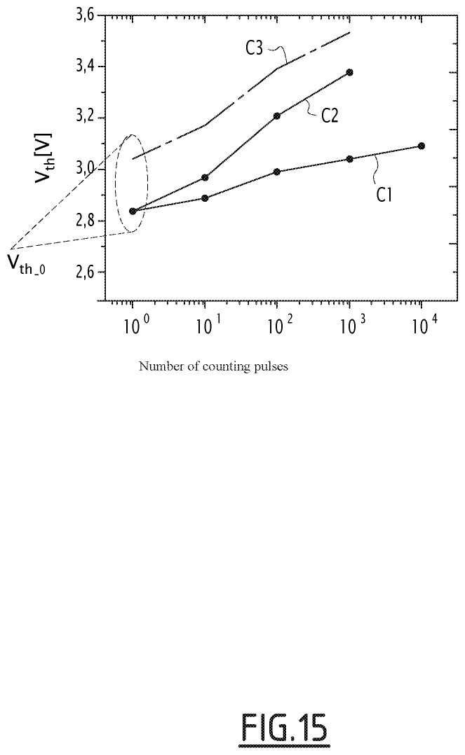

FIG. 15 is a graph making it possible to compare the evolutions of the switching voltage of FIGS. 5 and 14,

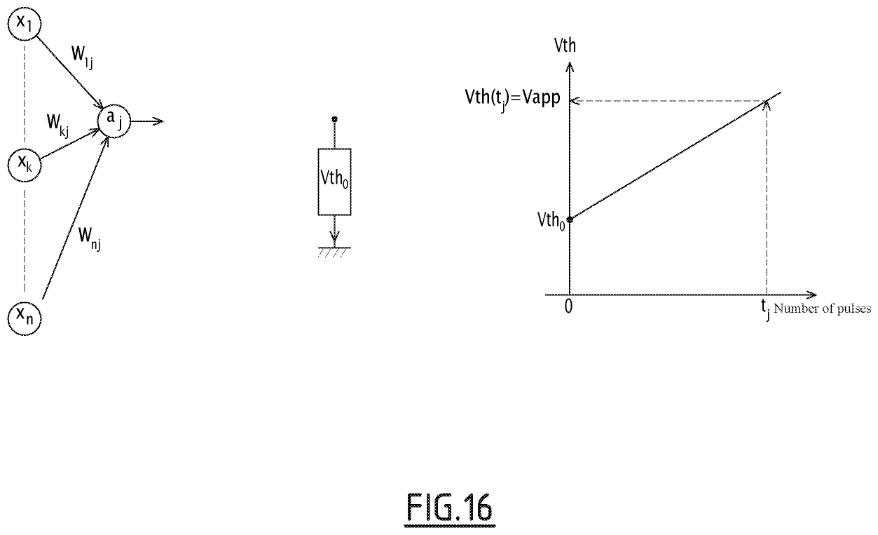

FIGS. 16 to 20 schematically illustrate an operation of the component of FIG. 1 to produce a neuron of a neural network with a binary output,

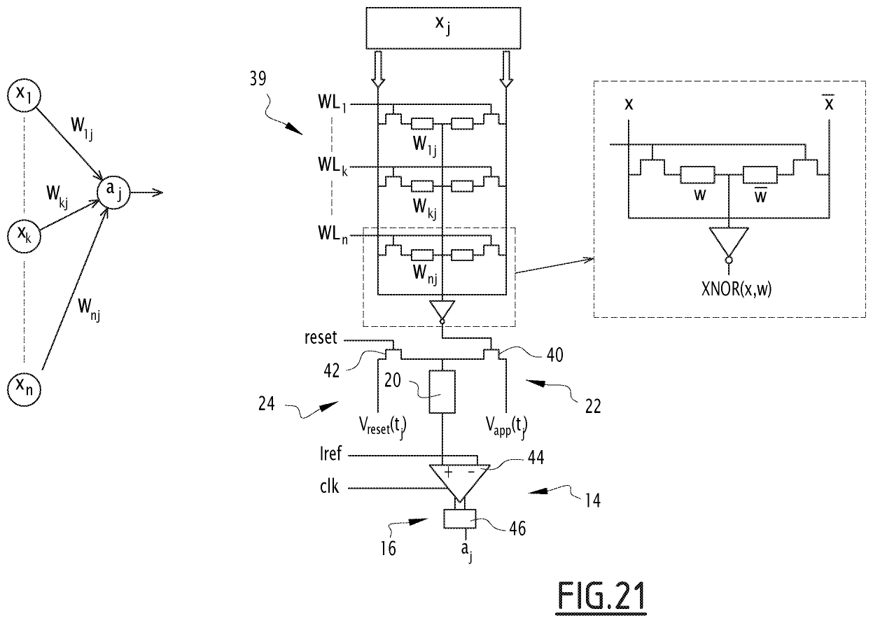

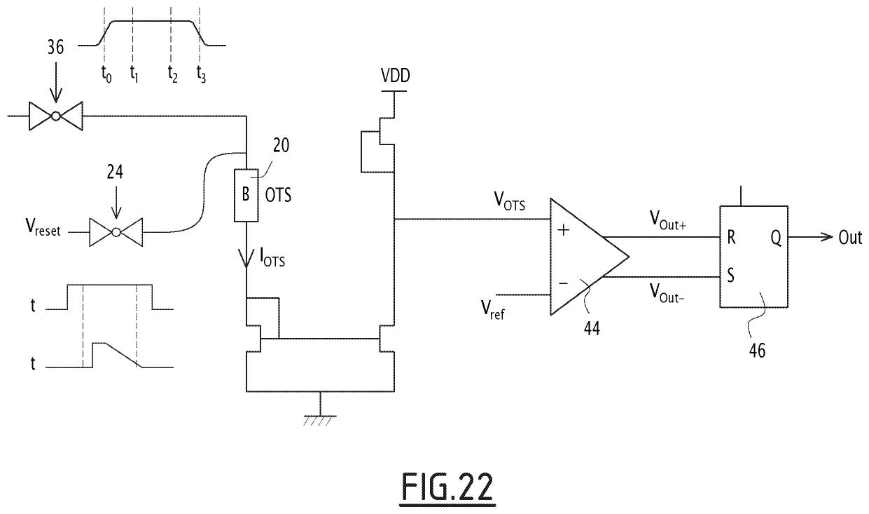

FIGS. 21 and 22 are schematic representations of an electronic circuit implementing a neuron and comprising the component of FIG. 1, and

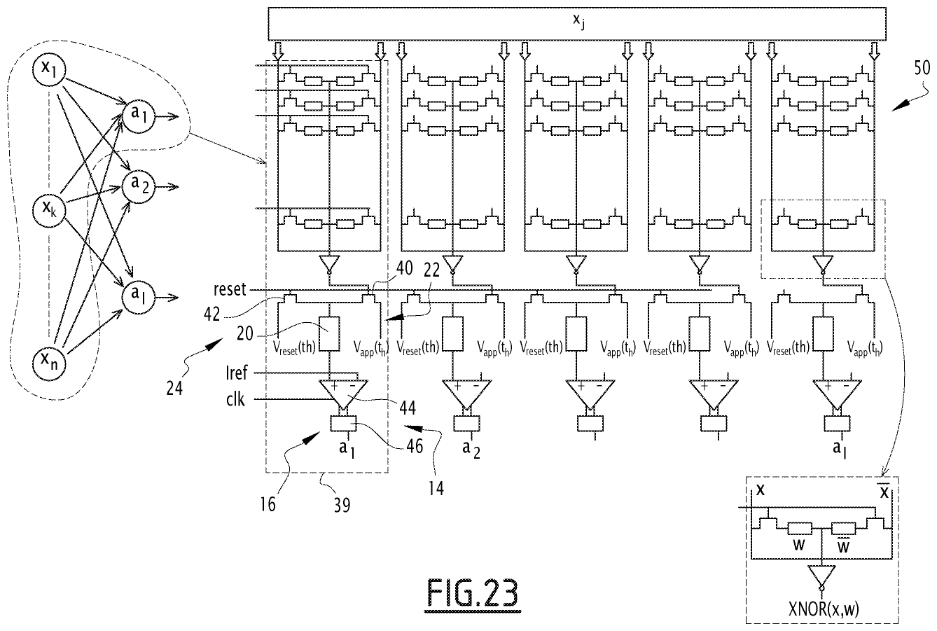

FIG. 23 is an example of neuromorphic circuit suitable for implementing a neural network with a binary output and comprising the component of FIG. 1.

An accumulation-comparison device 10 is an accumulator-comparator that is suitable for carrying out an accumulation and comparison operation

The operation of the accumulation-comparison device 10 can thus be represented as visible in FIG. 2 since the accumulation-comparison device 10 seeks to perform an operation written mathematically as follows:

sign(Σᵢαᵢ−B)
Where:
sign(X) is the function giving the sign of X,
αᵢ designates the bits equal to 1 or 0,
B designates an integer threshold.

The accumulation-comparison device 10 comprises a counting module 12, a comparison unit 14 and a storage unit 16.

The counting module 12 is suitable count a number of detection of events in a counting time interval.

In the example that will be described, the event is an activation of a neuron.

However, this is not limiting, the counting module 12 is, for example, usable for counting a number of detection of an object by a camera.

More generally, the counting module 12 is in connection with a detector of the event, the detector of the event providing it with a signal of detection of an event.

The different units of the counting module 12 are visible in FIG. 1.

The counting module 12 comprises an input unit 18, a selection component 20, an application unit 22 and a resetting unit 24.

The input unit 18 is suitable for receiving each signal of detection of an event in the counting time interval.

According to the example of FIG. 3, the selection component 20 is a selector 26.

Because a single selector is present, the selection component 20 is a device called a 1S device.

A selector has the function of blocking the passage of current at low voltage and allowing the passage of a strong current density when a threshold voltage is reached.

In the present case, the selector is an OTS-type selector, that is to say a selector having the current-voltage characteristic curve visible in FIG. 4.

This curve shows that an OTS selector makes it possible to have a reversible, symmetrical, bipolar volatile switching between a highly resistive OFF state and a conductive ON state.

The abbreviation “OTS” refers to the English designation “Ovonic Threshold Switching” meaning literally “ovonic threshold switching.”

As visible in FIG. 3, the selector 26 comprises a first electrode 28, a second electrode 30 and an active layer 32.

The electrodes 28 and 30 are each made in a conductive material which may be different or the same for the two electrodes 28 and 30.

The conductive material is, for example, chosen from TIN, TaN, W, TiWN, TiSiN or WN.

The active layer 32 is disposed between the first electrode 28 and the second electrode 30.

The active layer 32 is made of a chalcogenide material.

A chalcogenide is a dianion formed from a chemical element of the chalcogen family (typically selenium and tellurium), which has gained two electrons.

Here the chalcogenide material is a chalcogen alloy, preferably, the chalcogenide material is an alloy comprising As, Sb or Ge.

More specifically, the chalcogenide material is, for example GeSeSbN, GeSeAsTe or SeAsGeSi.

As indicated previously, the selector 26 has the behavior illustrated by the current-voltage characteristic curve of FIG. 4.

The application of an electrical pulse having an amplitude greater than a threshold voltage (or switching voltage) denoted Vt between the two electrodes 28 and 30 of the selector 26 causes a switching of the selector between a first resistive state (OFF state) and a second resistive state (ON state).

The amplitude is here defined as the potential difference between the two electrodes 28 and 30 of the selector 26.

Moreover, the electrical pulse must also apply a current on the selector 26 higher than the holding current of the selector 26 in the second resistive state to ensure stable switching.

The holding current is visible in FIG. 4 and is denoted Ihold.

Such an electrical pulse is denoted switching pulse in the following, this switching pulse making it possible to switch between the OFF state and the ON state.

As visible in FIG. 4, the resistance gap between the OFF state and the ON state is very significant, the OFF state corresponding to a very high resistance, typically a value 10 times greater, preferably a value 100 times greater.

Such a switching carried out by a switching pulse is often designated by the designation “OFF-ON” switching with reference to the corresponding English designation and the threshold voltage.

Thus, when a switching pulse is applied, the selector 26 is in the ON state and a current denoted ION passes through the selection component 20.

The current ION Is limited by the presence of an access transistor. The current ION is sometimes called compliance current and is much higher than the holding current Ihold of the selector 26.

Conversely, when an electrical pulse of amplitude lower than the threshold voltage denoted Vₜₕ and/or corresponding to a current strictly lower than the holding current Ihold of the selector 26 is applied, the selector 26 remains in the OFF state and a current denoted lₗₑₐₖ passes through the device 10, the current leak being much lower than the current ION.

As visible in FIG. 4, each switching pulse has a rising edge FM, a plateau P and a falling edge FD.

Among these switching pulses, some have a specific shape called first predefined shape and have the effect of increasing the threshold voltage value of the selector 26.

In the following, these switching pulses are called pulses of first shape.

Examples of pulses of first shape are schematized in FIG. 5.

Each of the pulses of first shape have in common that they have a relatively short falling edge FD1 and plateau P1.

The duration of the falling edge FD1 of a pulse of first shape is less than or equal to 100 nanoseconds (ns), preferably less than or equal to 50 ns.

The duration of the plateau P1 of a pulse of first shape is less than or equal to 100 ns.

As appears in FIG. 5 and in particular the examples of the center and of the right, the plateau P1 can be greatly reduced to a zero value.

Moreover, the comparison between the examples of the center and of the right also shows that the duration of the rising edge FM1 is not critical here for the pulses of first shape.

In the presence of such pulses of first shape, the threshold voltage of the selector 26 increases as a function of the number of pulses applied between the two electrodes 28 and 30.

This increase in the threshold voltage as a function of the number of switching pulses is represented in FIG. 6 for a compliance current of 100 μA.

In this example of FIG. 6, the pulses of first shape have the same polarity. By polarity is meant here the fact that a pulse takes only voltage values of the same sign.

It is observed that, starting from an initial threshold voltage denoted Vino of the order of 2.85 V, the value of the threshold voltage increases with the number of pulses of first shape to reach a value of 3.1 V for 10000 pulses of first shape.

Because of this, the pulses of first shape are counting pulses in the sense that they allow an increase in the threshold voltage value of the selector 26 which depends on the number of counting pulses applied.

The role of the application unit 22 of the counting module 12 is to apply these counting pulses for each detection signal received by the input unit 18.

With reference to FIGS. 7 to 11, it is possible to exploit this variation of the threshold voltage to carry out an accumulation function.

For this, it is supposed that the evolution of the threshold voltage of the selector 26 as a function of the number of counting pulses is known.

A number of counting pulses to be accumulated is chosen. This number is an accumulation threshold denoted B in the following.

This accumulation threshold B will be chosen as a function of the desired application for the accumulation-comparison device 10.

The accumulation threshold B is equal to 1000 counting pulses in the example of FIG. 7 and is represented schematically by a vertical dotted line.

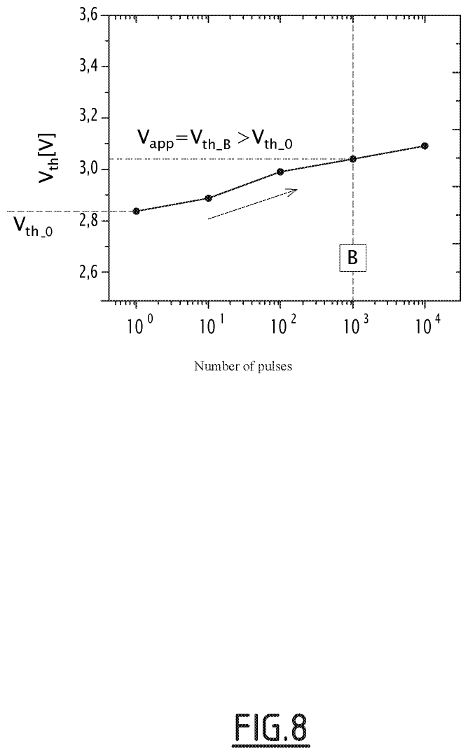

As represented in FIG. 8, from this accumulation threshold B, a final threshold voltage value is obtained, that is to say the maximum value reached by the threshold voltage of the selector 26 during the accumulation. This voltage value is denoted V_{th_B}

In the present case, for an accumulation threshold B of 1000, the final threshold voltage value V_{th_B} is equal to 3.05 V.

The final threshold voltage value defines in this case the amplitude of the counting pulses to be applied between the two electrodes 28 and 30.

More precisely, a counting pulse has an amplitude of V_{th_B} in addition to the aforementioned conditions, namely that the shape of the counting pulse is according to the first shape and that the current applied by the counting pulse is greater than or equal to the holding current Ihold.

This leads to operation according to two configurations for the selection component 20 according to the threshold value reached by the selector 26.

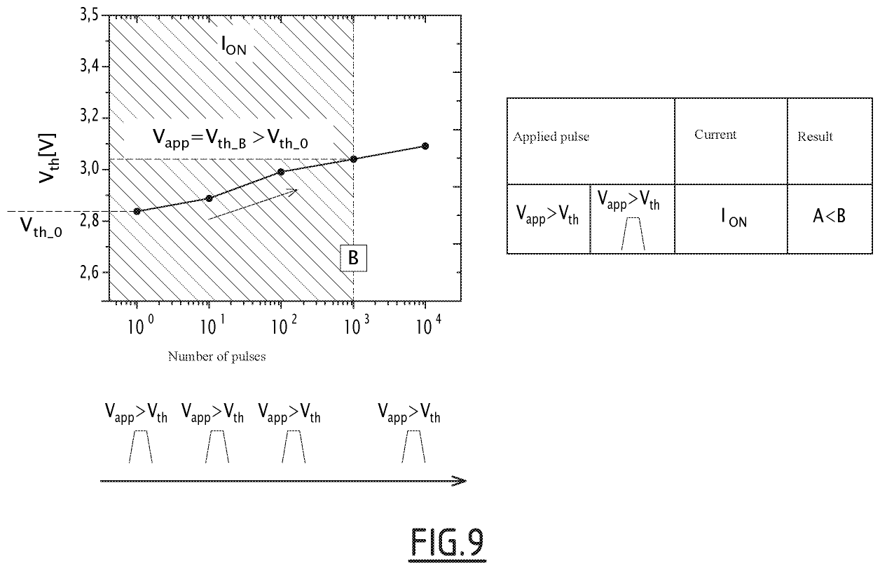

In a first configuration corresponding to the case of FIG. 9, each counting pulse induces an increase in the value of the threshold voltage Vₜₕ because the value of the amplitude of the counting pulse is greater than the value of the threshold voltage Vₜₕ. This corresponds to the fact that the number of counting pulses is strictly less than the accumulation threshold B.

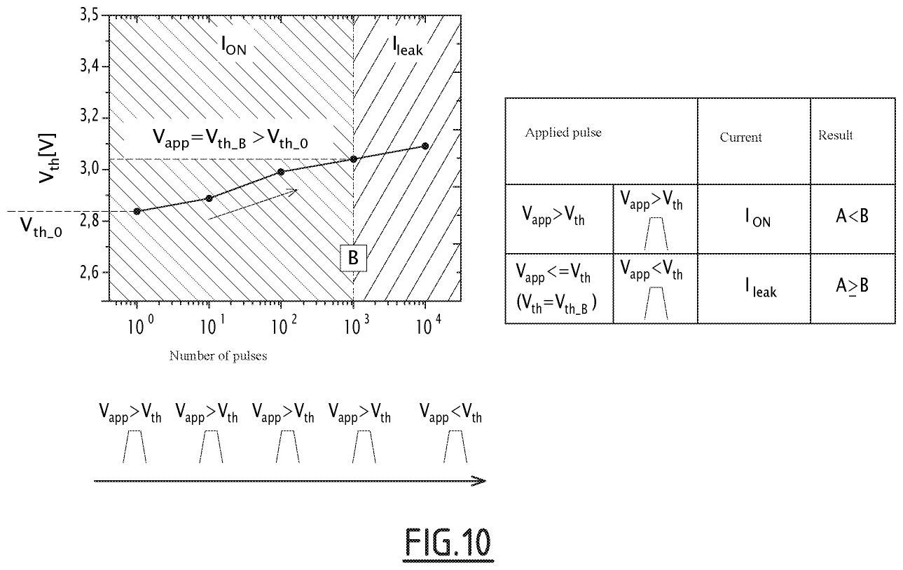

In a second configuration corresponding to the case of FIG. 10, the value of the applied voltage is still V_{th_B} but the threshold voltage reached by the selector 26 is also equal to V_{th_B}, such that the voltage applied by the application unit 22 does not comply with the switching condition according to which the applied voltage is greater than or equal to the threshold voltage of the selector 26. In this case, it is no longer possible to generate a switching of the selector 26 and the current remains less than or equal to Iₗₑₐₖ.

An accumulation function up to the accumulation threshold B during a time interval, called counting time interval, is thus indeed carried out.

The resetting unit 24 makes it possible to carry out a resetting of the counting time interval, which makes it possible to use the counting module 12 several times.

For this, the resetting unit 24 is suitable for applying pulses of a second predefined shape between the two electrodes 28 and 30.

The pulses of second shape are switching pulses, and as such apply on the selector 26 a compliance current stronger than the holding current Ihold and than the current applied by the counting pulses.

Two examples of pulses of second shape are represented in FIG. 11.

Each of the pulses of second shape have in common that they have a relatively long plateau P2.

Typically, the duration of the plateau P2 of a pulse of second shape is greater than or equal to 200 ns, preferably greater than or equal to 700 ns.

Advantageously, as is the case for the example on the left of FIG. 11, the duration of the falling edge FD2 is also relatively long, for example greater than or equal to 200 ns, preferably greater than or equal to 500 ns.

More generally, the second shape may be determined from the first shape by imposing that the ratio between the duration of the sum of the plateau P2 and of the falling edge FD2 for the second predefined shape and the duration of the sum of the plateau P1 and of the falling edge FD1 for the first predefined shape be greater than or equal to 2.

This ratio is, preferably, greater than or equal to 5, advantageously greater than or equal to 10.

Insofar as the falling edges FD1 and FD2 may be very short, the preceding ratio is, in some embodiments, equal to the ratio between the plateaus P2 and P1.

Moreover, the comparison between the examples of FIG. 11 also shows that the duration of the rising edge FM2 is not critical here for the pulses of second shape.

In the presence of such pulses of second shape, the threshold voltage of the selector 26 decreases to the minimum threshold voltage value of the selector 26 (that is to say a zero number of counting pulses).

These pulses of second shape therefore constitute resetting pulses.

In the described example, this corresponds to applying a pulse such as visible on the table of FIG. 12, this resetting pulse having the effect of causing the selector 26 to switch and of causing the threshold voltage value of the selector 14 returns to its initial value V_{th_0}.

The accumulation-comparison device 10 has then returned to its first configuration and can again be used as an accumulator-comparator with the same accumulation threshold B or a new accumulation threshold if this is desired by simply changing the value of the voltage applied by each counting pulse.

A means for simply carrying out a change of the accumulation threshold B is to have at the input unit 18 a receiving sub-unit 34 and a conversion sub-unit 36.

The conversion sub-unit 36 serves to convert the signal of detection of an event of an event received by the receiving sub-unit 34 into a counting pulse.

It suffices to modify the maximum value of the output pulses of the conversion sub-unit 36 to modify the accumulation threshold B.

The component 10 thus makes it possible to exploit the behavior of the selection component 20 to carry out an accumulation operation.

The component 10 has the advantage of simplicity insofar as this operation is carried out at the level of the selector 26.

Another embodiment of the selection component 20 is represented in FIG. 13.

According to the example of FIG. 13, the selection component 20 comprises a selector 26 and a resistive memory 38 in series with the selector 26.

More precisely, the resistive memory 38 is formed in the selection component 20 which is formed by five layers, namely the first electrode 28 (which is the lower electrode of the selection component 20), the active layer 32 (that of the selector 26), the second electrode 30 (which is the intermediate electrode separating the selector 26 and the resistive memory 38), a second active layer 37 (which is the active layer corresponding to the resistive memory) and a third electrode 39 (serving as upper electrode of the selection component).

In this case, the resistive memory 38 can have two states, a high state and a low state. Of course, the number of states of the resistive memory 38 may be chosen greater if this is desirable for the contemplated application

The high state corresponds to a high resistance and is generally designated by the abbreviation HRS referring to the English term “High Resistive State” which means literally highly resistive state. The high state is, because of this, called high state HRS in the following.

The low state corresponds to a low resistance and is generally designated by the abbreviation LRS referring to the English term “Low Resistive State” which means literally low resistive state. The low state is, because of this, called low state LRS in the following.

The resistive memory 38 is, for example, a phase-change memory (PCM memory) or a ReRAM memory.

In this case, the selection component 20 is a device in 1S1R configuration (that is to say a 1 selector with 1 resistive element configuration).

The central part and the right part of FIG. 13 illustrate the current-voltage characteristic of the selection component 20 respectively for a resistive memory 38 programmed to the LRS state and to the HRS state.

In each of the cases, for the case of a switching pulse whose voltage is positive, a switching pulse having an amplitude greater than the considered threshold makes it possible to obtain a switching. This switching pulse also implies that the selection component 20 sees a current higher than the holding current of the selector 26 but lower than the reprogramming current of the resistive memory 38.

In the case of a resistive memory 38 programmed to the LRS state, the threshold voltage value is V_{th-LRS} whereas, in the case of a resistive memory 38 programmed to the HRS state, the threshold voltage value is V_{th-HRS} which is greater than the threshold voltage value in the LRS state of V_{th-LRS}.

When the resistive memory 38 is programmed to the HRS state, the applied voltage must be greater than Vₜₕ′=V_{th-HRS} to cause the selector 26 to switch. When the resistive memory 38 is programmed to the LRS state, the applied voltage must be greater than Vth′=Vth-LRS to cause the selector 26 to switch.

FIG. 14 shows that the successive application of counting pulses at an amplitude strictly greater than V_{th′} leads to the same effect of increasing the value of the threshold voltage.

For the example of FIG. 14, a resistive memory 38 programmed to the LRS state with a compliance current of 100 μA was considered to avoid reprogramming the resistive memory 38 during the successive switchings of the selector 26.

The physical phenomenon observed being the same as previously, the selection component 20 according to the embodiment of FIG. 13 may also be used as accumulator-comparator.

To properly understand the interest of such an embodiment in 1S1R configuration relative to a 1S configuration, the variation of the value of the threshold voltage as a function of the number of counting pulses applied observed in FIG. 14 is to be compared to that of FIG. 5.

For this, there has been reported with the same scale, in FIG. 15, the variation for a selector 26 alone (curve C1), the variation for a selector 26 with a resistive memory 38 in the LRS state (curve C2) and the variation for a selector 26 with a resistive memory 38 in the HRS state (curve C3).

The comparison of curves C2 and C3 corresponding to the LRS state and to the HRS state shows that the initial threshold voltage V_{th_0} is not the same in the states.

More precisely, the more the resistive memory 38 is programmed with a high resistivity, the more the initial threshold voltage Vth_0 will become large.

The selection component 20 therefore allows, through the choice of the resistance value of the resistive memory 38, to also control the value of the initial threshold voltage V_{th_0}.

In each of the cases, such an accumulation-comparison device 10 can be used in a physical embodiment of a neuron of a binary neural network.

Such a use is illustrated with reference to FIGS. 16 to 20.

The structure of a binary neuron is illustrated schematically on the left part of FIG. 16.

A given binary neuron has n inputs xi, which are multiplied by their corresponding synaptic weights wi. In this notation, the index i is an integer varying between 1 and n.

The inputs and the weights are binary and can only have two values, which are here equal to 0 and 1.

More precisely, a binary neural network is characterized by weights and activations of values 1 and −1. But the negative activations and weights (−1) are exchanged by “0” in order to assimilate it to an XNOR operation

Thus, the multiplication between an input and a synaptic weight amounts to performing a simple XNOR operation.

The results of the multiplications between the inputs and the weights are then summed (popcount operation), and compared to a threshold tj. If the sum is greater than the threshold, the output of the neuron will be equal to 1, otherwise, it will be equal to 0.

Stated otherwise, the output of the neuron is written mathematically as follows:

αⱼ=sign POPCOUNTᵢ(XNOR(w_{i,j}xᵢ)−tⱼ))

The right part of FIG. 16 shows the initial state of the neuron. The device has then been initialized at its initial threshold voltage Vth_0.

There is chosen as voltage Vapp for the counting pulses a value equal to Vₜₕ (tⱼ), that is to say when the value of Vth when the number of counting pulses applied to the selector 26 is equal to the threshold tj.

It is then a matter of accumulating the successive XNOR(w_{i,j},xᵢ).

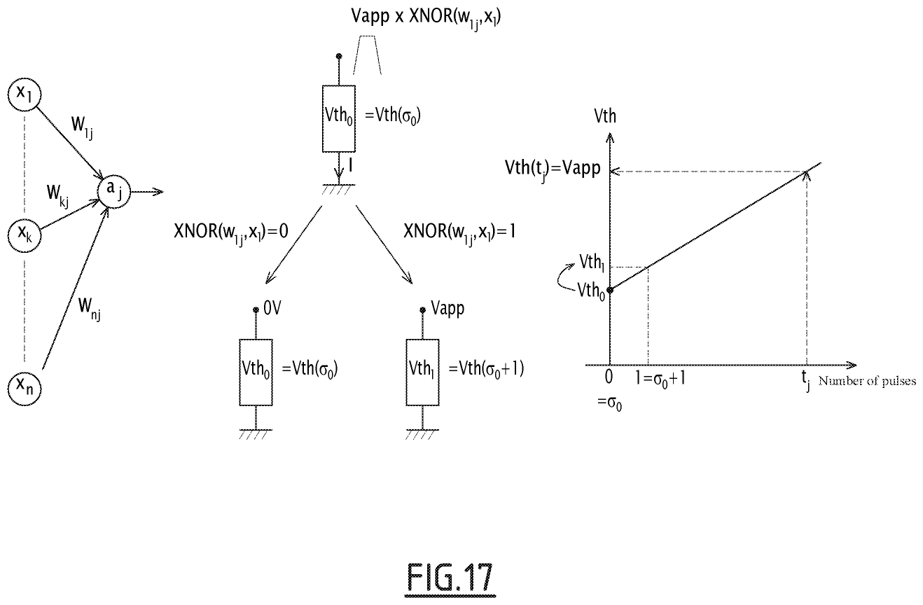

FIG. 17 then illustrates what happens at the first accumulation of the neuron.

As illustrated in this figure, a switching pulse of amplitude Vₐₚₚ*XNOR(w_{1,j}, x₁) is applied on the selector 26

For the following, σₖ is defined as follows:

$${σ}_{k} = {\sum }_{i = 1}^{k} XNOR ( {w}_{i , j} , {x}_{i} )$$

This term σₖ may be interpreted as a partial popcount (for which i has only been accumulated up to k).

According to a first case, XNOR(w_{1,j},x₁)=0.

In this case, the amplitude of the counting pulse is zero. It results therefrom that the threshold voltage of the selector 26 is:

Vₜₕ(σ₁)=Vₜₕ(σ₀)=V_{th_0}

According to a second case, XNOR(w_{1,j},w₁)=1.

In this case, the partial popcount is incremented by 1 and the amplitude of the counting pulse is Vₐₚₚ, which has the effect of increasing the threshold voltage of the selector 26 to a value Vₜₕ (σ₁)>Vₜₕ(σ₀).

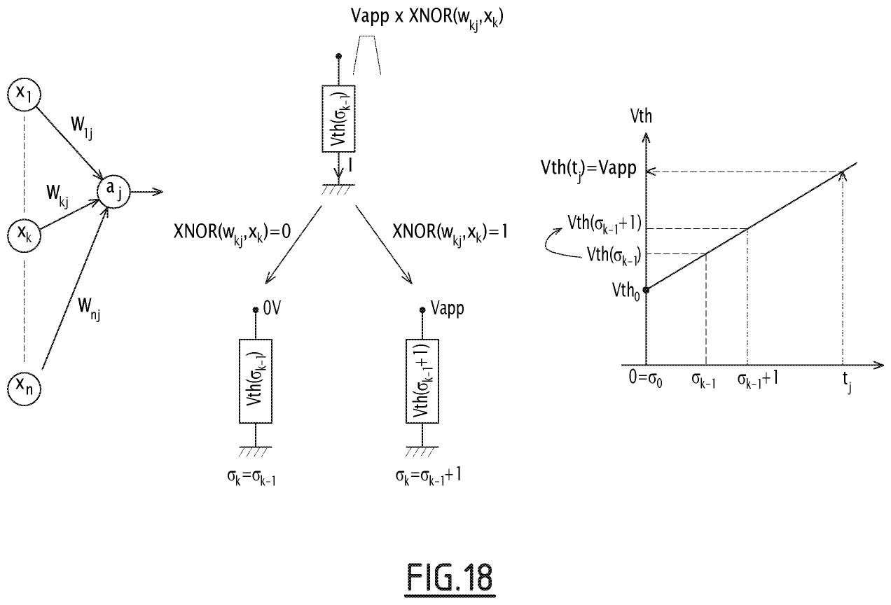

FIG. 18 illustrates what happens for the kth accumulation.

A counting pulse of amplitude Vₐₚₚ*XNOR(w_{k,j},xₖ) is applied on the selector 26.

According to a first case, XNOR(w_{k,j},xₖ)=0.

In this case, the amplitude of the counting pulse is zero. It results therefrom that the threshold voltage of the selector 26 is:

Vₜₕ(σₖ)=Vₜₕ(σₖ₋₁)

According to a second case, XNOR(w_{k,j},xₖ)=1.

In this case, the partial popcount is incremented by 1 and the amplitude of the counting pulse is Vₐₚₚ, which has the effect of increasing the threshold voltage of the selector 26 to a value Vₜₕ(σₖ)>Vₜₕ(σₖ₋₁).

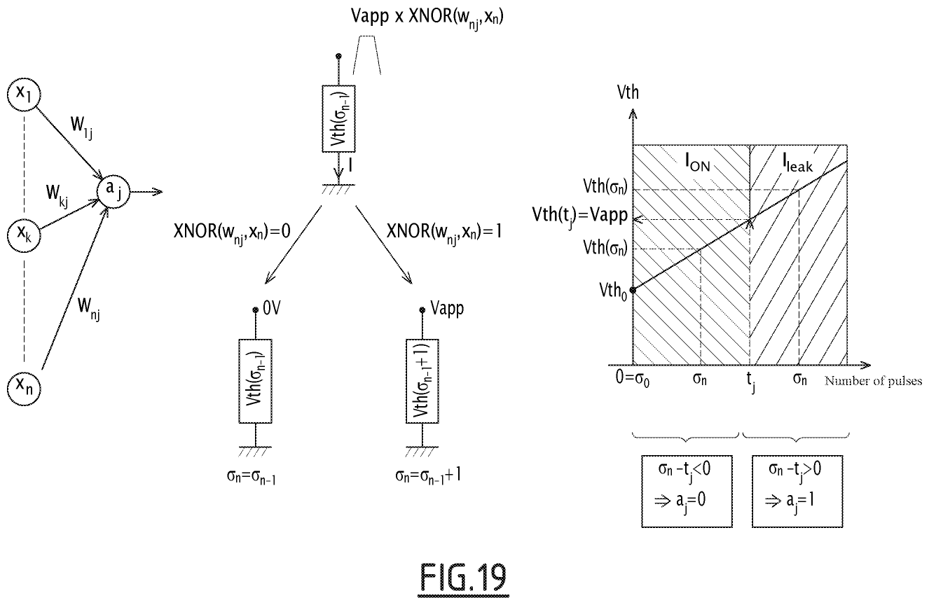

FIG. 19 schematically illustrates the implementation of the last iteration which takes place similarly.

As previously, two cases are possible.

According to a first case, σₙ<tⱼ.

In this case, the amplitude of the mth counting pulse has not generated the opening of the selector 26 and resulting in an observation of the current Ith, because the threshold of the selector 26 is lower than the popcount.

In this notation, m is the value of the index k corresponding to the last XNOR(w_{k,j},xₖ)=1.

It can also be noted that the following relation holds:

$${POPCOUNT}_{i} ( XNOR ( {w}_{i , j} , {x}_{i} ) ) = {\sum }_{i = 1}^{m} XNOR ( {w}_{i , j} , {x}_{i} ) = {σ}_{m}$$

The amplitude of the mth count pulse Vₐₚₚ*XNOR(w_{m,j},xₘ) generated such an opening because:

Vₜₕ(σn)=Vₜₕ(σₘ)<Vₜₕ(tⱼ)=Vₐₚₚ

This relationship holds because σₘ=σₙ<tⱼ.

This case corresponds to a neuron output of 0.

In a second case, σₙ>tⱼ.

In this case, the amplitude of the mth counting pulse Vₐₚₚ*XNOR(w_{m,j},xₘ) did not cause selector 26 to open, resulting in an observation of current Ith, because the threshold of selector 26 is lower than the popcount.

This case corresponds to a neuron output at 1.

According to one embodiment, it is advantageous to stop the counting as soon as a counting pulse does not generate the opening of the selector 26, which would make it possible to avoid carrying out the accumulation beyond a pulse which has already made it possible to exceed the threshold and therefore to obtain a neuron output at 1.

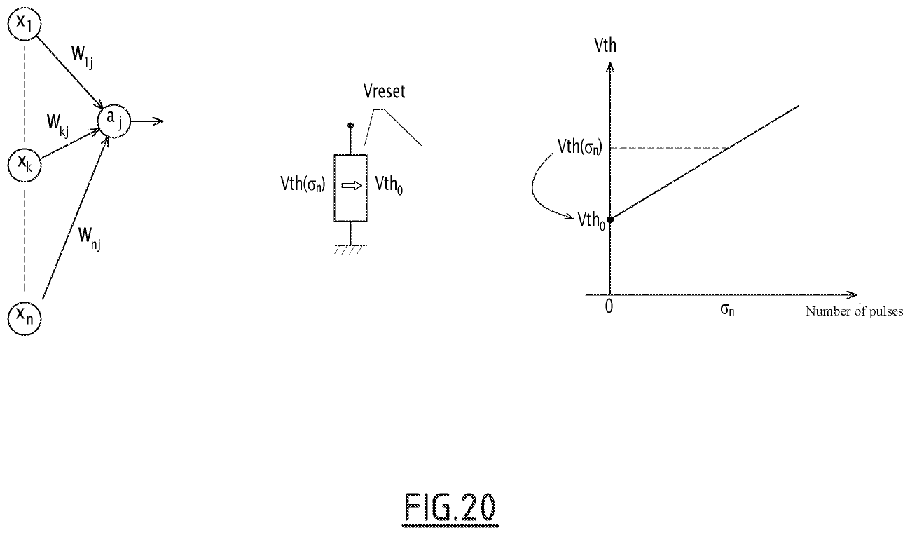

As illustrated very schematically in FIG. 20, after this accumulation, an operation of resetting the value of the threshold voltage by application of a resetting pulse is implemented.

This operation may be exploited in an electronic circuit 39 implementing a neuron such as that of European application EP 4 137 999 published on Feb. 22, 2023 and whose content is inserted here by reference.

As a reminder, this electronic circuit 39 illustrates the particular case of a binary neuron based on resistive memory to compute the XNOR operations between the weight and the inputs: the weights of the neuron are stored differentially in 2T2R structures, the inputs xi are applied sequentially on the bit line and its complement, and the source line is connected to an inverter.

Within a same column the ith line stores the weight of index i. Thus, it suffices to sequentially activate the word lines WLi one after the other to be able to generate the successive XNOR(w_{k,j},xₖ).

Very schematically as visible in FIG. 21, the accumulation-comparison device 10 is located at the bottom of the column. The accumulation-comparison device 10 comprises the selection component 20 which is connected to the comparison unit 14.

The application unit 22 is a first transistor 40 controlled by the output of the inverter (and therefore by the successive XNOR(w_{k,j},xₖ), making it possible to apply the counting pulses.

The resetting unit 24 is here also a second transistor 42 making it possible to apply the resetting pulse on the selection component 20.

The comparison unit 14 comprises a comparator 44 making it possible to compare the current Iread relative to a reference current I_{ref}=(I_{ON}+Iₜₕ)/2.

At the output of the comparator 44, a storage unit 16 makes it possible to force a “1” at its output as soon as the threshold of the neuron has been exceeded.

The storage unit 16 is here a flip-flop 46.

In operation, it is supposed that the selector 26 has undergone a resetting so that the threshold voltage is at the initial value Vth_0 (by using the second transistor 42)

Then, the first word line WL1 is activated which gives a first value XNOR(w_{1,j},x₁). In the case where this value is equal to 1, the first transistor 40 applies a switching pulse.

The output value of the selector 26 is compared by the comparator 44 to the reference current and the result is stored in the flip-flop 46.

Similarly, the second word line WL2 is activated which gives a second value XNOR (w_{1,j},x₁). In the case where this value is equal to 1, the second transistor 42 applies a switching pulse.

The output value of the selector 26 is compared by the comparator 44 to the reference current and the result is stored in the flip-flop.

And so on for each of the word lines.

It will then suffice to read the value of the flip-flop 46 to determine whether the output of the neuron is equal to 0 or 1.

A practical example of implementation of the functions that have just been described for the electronic circuit is represented in FIG. 22.

In this case, the selector 26 is connected to a current mirror making it possible to copy the value of the output current of the selector 20 to obtain a voltage V_{OTS} to be compared to a reference V_{Ref}.

The reference will be chosen as corresponding to the median value of the extreme values that the selector 26 can take, either because this value is known or by use of a current mirror assembly with another selector which would be in the OFF state when one wants to generate the reference.

In this electronic circuit 39, the pulse threshold B may be controlled in several ways.

The choice of the amplitude of the counting pulses thanks to the conversion sub-unit 36, which is here a controllable switch, has already been presented.

The choice of the resistance value of the resistive memory 38 is another way of varying the value of the pulse threshold B.

Another idea is to artificially add additional pulses (for example by using additional columns of RRAM), which will decrease the value of B by a value depending on the number of these additional pulses.

This electronic circuit 39 is intended to form part of a neuromorphic circuit 50 suitable for implementing a neural network with a binary output as this is schematized in FIG. 23.

A neuromorphic circuit 50 capable of implementing a binary neural network with better integrability in an assembly of memory cells is thus obtained.

This neuromorphic circuit 50 thus advantageously exploits a counting module 12 which is capable of counting a number of detections of events in a counting time interval.

The counting module 12 comprises the input unit 18, the selection component 20, the application unit 22 and the resetting unit 24.

The number of events to be detected is then accessible with the value of the threshold voltage of the selector 26.

In the application cases where it is desired to know the number of events to be detected, the counting module 12 may also comprise an additional measurement unit suitable for determining the value of the threshold voltage of the selector 26.

1. Module for counting a number of detections of events in a counting time interval, the counting module comprising:
an input unit adapted to receive a signal of detection of an event in the counting time interval,
a selection component, the selection component comprising a selector comprising a first electrode, a second electrode and an active layer disposed between the first electrode and the second electrode, the active layer being made of a chalcogenide material,
the selector being adapted to switch between a first resistive state and a second resistive state in the presence of a switching pulse applied between the two electrodes, the first resistive state being more resistive than the second resistive state, a switching pulse being a pulse having an amplitude exceeding a threshold voltage value and applying a current on the selector higher than the holding current of the selector in the second resistive state,
an application unit adapted to apply a counting pulse on the selector for each detection signal received by the input unit,
each counting pulse being a switching pulse having a first predefined shape increasing the value of the threshold voltage of the selector, the threshold voltage value of the selector thus being representative of the number of detections of events, and
a unit for resetting the counting time interval, the resetting unit being adapted to apply at least one resetting pulse on the selector, a resetting pulse being a switching pulse having a second shape and decreasing the threshold voltage of the selector to a minimum threshold voltage value of the selector

2. Counting module according to claim 1, wherein each switching pulse has a rising edge, a plateau at a maximum value and a falling edge, the ratio between the duration of the sum of the plateau and of the falling edge for the second predefined shape and the duration of the sum of the plateau and of the falling edge for the first predefined shape being greater than or equal to 2.

3. Counting module according to claim 2, wherein each switching pulse has a rising edge, a plateau at a maximum value and a falling edge, the ratio between the duration of the sum of the plateau and of the falling edge for the second predefined shape and the duration of the sum of the plateau and of the falling edge for the first predefined shape being greater than or equal to 10.

4. Counting module according to claim 2, wherein the duration of the plateau of a resetting pulse is greater than or equal to 200 ns.

5. Counting module according to claim 2, wherein the duration of the falling edge of a resetting pulse is greater than or equal to 200 ns.

6. Counting module according to claim 2, wherein the duration of the falling edge of a counting pulse and the duration of the plateau of a counting pulse are each less than or equal to 100 ns.

7. Counting module according to claim 1, wherein the input unit comprises a sub-unit for converting the signal of detection of an event received into a counting pulse.

8. Counting module according to claim 1, wherein the selection component further comprises a resistive memory, the resistive memory having at least two distinct resistance values, the resistive memory being interposed between an electrode and the active layer, the threshold voltage value of the selector also depending on the resistance value of the resistive memory.

9. Device adapted to carry out an accumulation operation and a comparison operation, the device comprising a counting module according to claim 1, the application unit being adapted to apply counting pulses having an amplitude equal to a threshold voltage value of the selector corresponding to a threshold of detections of events to be reached, the device further comprising:
a comparison unit adapted to compare a quantity representative of the value of the threshold voltage of the selector with a quantity representative of a predefined threshold voltage, the predefined threshold voltage corresponding to a predefined number of counting pulses, to obtain a comparison result, and
a unit for storing the result of the comparison.

10. Device according to claim 9, wherein the comparison unit comprises a current comparator, the quantity representative of the value of the threshold voltage of the selector being the output current of the selector and the quantity representative of the predefined threshold voltage being a current value.

11. Device according to claim 9, wherein the storage unit is a flip-flop.

12. Device according to claim 9, wherein the application unit is a transistor.

13. Device according to claim 9, wherein the resetting unit is a transistor.

14. Electronic circuit implementing a neuron comprising a device according to claim 9.

15. Neuromorphic circuit adapted to implement a neural network with a binary output, the neuromorphic circuit comprising at least one electronic circuit implementing a neuron according to claim 14.
